(19) United States
(12) Patent Application Publication
(10) Pub. No.: US 2006/0258051 A1
(43) Pub. Date: Nov. 16, 2006

(54) Method and system for solder die attach

(75) Inventor: Bernhard Lange, Garland, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED

(21) Appl. No.: 11/126,016

(22) Filed: May 10, 2005

(51) Int. Cl. H01L 21/00; H01L 21/67

(52) U.S. Cl. 438/113; 438/462; 438/464; 156/349

(57) ABSTRACT

According to one embodiment of the invention, a method of solder die attach includes providing a wafer disposed outwardly from a carrier tape, partitioning the wafer into a plurality of wafer sections, partially partitioning at least some of the wafer sections, picking up a first wafer section of the partially partitioned wafer sections, and placing the first wafer section onto molten solder disposed outwardly from a substrate.

### TECHNICAL FIELD OF THE INVENTION

This invention relates generally to the field of integrated circuit packaging and, more specifically, to a method and system for solder die attach for more than one die and reliability improvement for solder die attach for large die.

### BACKGROUND OF THE INVENTION

Solder is sometimes utilized to attach a die to a die pad on a leadframe or other substrate. Current process equipment can only attach a single die for each die pad. The die is placed in molten solder that is squeezed out from under the die before the placement nozzle is removed. This may cause an adjacent die to float away. In addition, depending on the size of the die and/or its intended use, cracks may develop in the solder during use because the solder may experience the stress due to the coefficient of thermal expansion (CTE) difference between the die and the leadframe.

### SUMMARY OF THE INVENTION

According to one embodiment of the invention, a method of solder die attach includes providing a wafer disposed outwardly from a carrier tape, partitioning the wafer into a plurality of wafer sections, partially partitioning at least some of the wafer sections, picking up a first wafer section of the partially partitioned wafer sections, and placing the first wafer section onto molten solder disposed outwardly from a substrate.

Some embodiments of the invention provide numerous technical advantages. Other embodiments may realize some, none, or all of these advantages. For example, embodiments of the invention facilitate the placement of two or more die on a leadframe or other substrate. In addition, large die sizes may be utilized because expected fracture areas may be accounted for in the solder die attach process. Another advantage may include monochannel chips that can be placed two times for dual or multichannel applications. No special redesign is necessary.

Other technical advantages are readily apparent to one skilled in the art from the following figures, descriptions, and claims.

### BRIEF DESCRIPTION OF THE DRAWINGS

For a more complete understanding of the invention, and for further features and advantages, reference is now made to the following description, taken in conjunction with the accompanying drawings, in which:

FIGS. 1A and 1B are plan and cross-sectional views, respectively, of a portion of a wafer in accordance with an embodiment of the invention;

FIGS. 2A and 2B are plan and cross-sectional views, respectively, of the portion of the wafer of FIGS. 1A and 1B illustrating a further processing step on the wafer;

FIG. 2C is a cross-sectional view of the portion of the wafer of FIGS. 1A and 1B according to another embodiment of the invention;

FIG. 3 is an elevation view illustrating the picking of a pair of die in accordance with an embodiment of the invention;

FIGS. 4A and 4B are plan views of the placement of a two-part die and two die, respectively, in accordance with an embodiment of the invention; and

FIG. 5 is a cross-sectional view of a integrated circuit package in accordance with an embodiment of the invention.

### DETAILED DESCRIPTION OF EXAMPLE EMBODIMENTS OF THE INVENTION

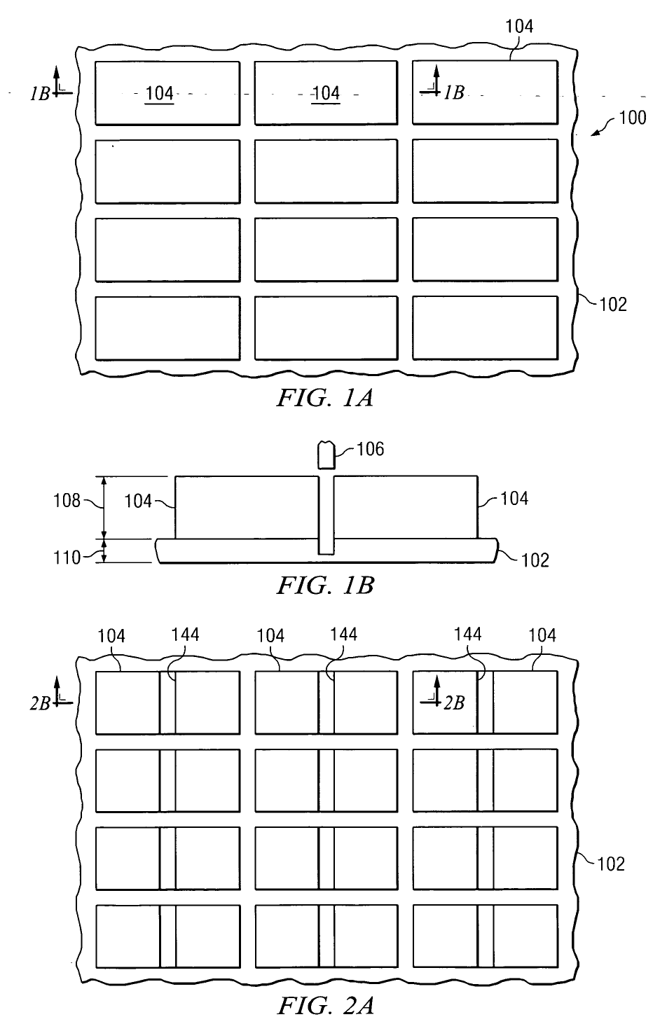

Example embodiments of the present invention and their advantages are best understood by referring now to FIGS. 1A through 5 of the drawings, in which like numerals refer to like parts.

FIGS. 1A through 5 illustrate systems and methods of solder die attach according to one or more embodiments of the invention. Embodiments of the invention may facilitate the placement of two or more integrated circuit die on a leadframe or other suitable substrate. In addition, large die sizes may be utilized because expected fracture areas may be accounted for in the solder die attach process, as described in further detail below.

FIGS. 1A and 1B are plan and cross-sectional views, respectively, of a portion of a wafer 100 disposed outwardly from a carrier tape 102 in accordance with an embodiment of the invention. Wafer 100 may be any suitably sized wafer formed from any suitable material, such as silicon or other semiconductor material having a solderable backside (not explicitly illustrated). In addition, carrier tape 102 may be any suitable substrate utilized to support wafer 100 during processing of wafer 100.

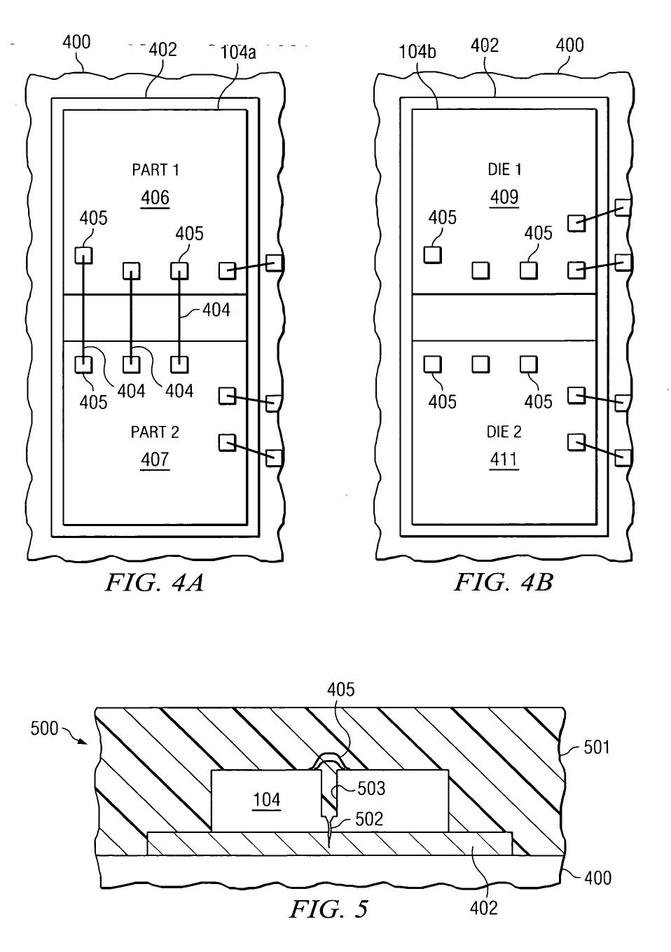

As illustrated in FIGS. 1A and 1B, wafer 100 is first partitioned into a plurality of wafer sections 104. This partitioning may be facilitated in any suitable manner, such as with a cutting device 106 (FIG. 1B), which may be any suitable cutting device, such as a saw. Cutting device 106 partitions wafer 100 into wafer sections 104 by cutting through a thickness 108 of wafer 100. In some embodiments, cutting device 106 may also cut at least partially through a thickness 110 of carrier tape 102. The partitioning of wafer 100 into wafer sections 104 may create any suitable arrangement of wafer sections 104, such as a rectangular or other type of array of wafer sections 104. Each wafer section 104 may be any suitable size and shape and, as described in further detail below in conjunction with FIGS. 4A and 4B, may include one die with separate die sections, two die, or multiple die.

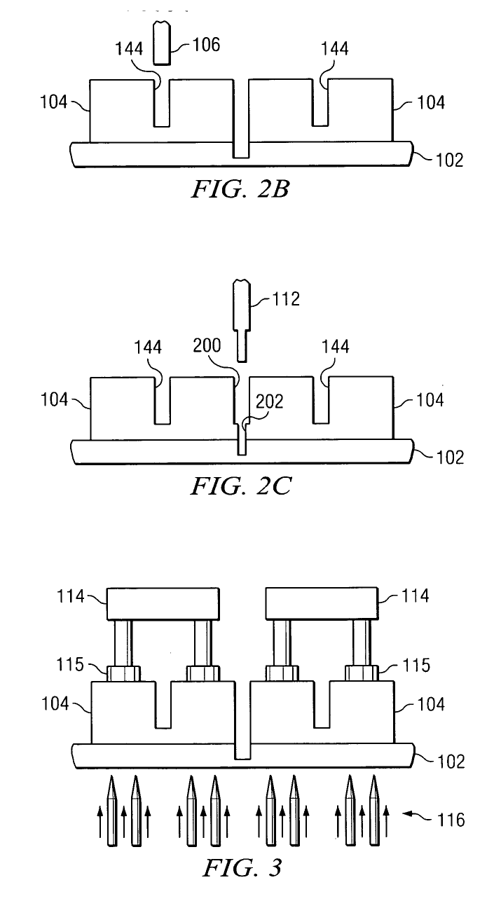

FIGS. 2A and 2B are plan and cross-sectional views, respectively, of wafer 100 illustrating a further processing step of wafer 100. As illustrated, at least some of the wafer sections 104 are partially partitioned by cutting device 106 or other suitable partitioning device to form respective channels 144. This partial partitioning results in a portion of thickness 108 of wafer 100 being removed. Preferably, a majority of thickness 108 is removed with cutting device 106. In addition, wafer sections 104 may be partitioned at any suitable location, such as at the approximate midsection of each wafer section 104.

FIG. 2C is a cross-sectional view of a portion of wafer 100 according to another embodiment of the invention in which a dual blade 112 is used to partition wafer 100 into separate wafer sections 104. In this embodiment, dual blade 112 is operable to cut wafer 100 to form a first trough 200 that extends through a majority of thickness 108 of wafer 100 and a second trough 202 extending from the bottom of first trough 200 down through the rest of thickness 108 of wafer 100 and possibly into carrier tape 102. Second trough 202 is thinner than first trough 200 when using dual blade 112 to partition wafer 100.

After wafer 100 is partitioned into wafer sections 104, according to FIGS. 1A and 1B, and one or more wafer sections 104 is partially partitioned, according to FIGS. 2A and 2B, then wafer sections 104 are ready to be transferred to a suitable substrate. This is accomplished by a vacuum device 114 having one or more vacuum nozzles 115 as illustrated in FIG. 3. FIG. 3 is an elevation view illustrating the “picking” of a wafer section 104 in accordance with an embodiment of the invention. Vacuum device 114 may be any suitable pick-and-place device used to remove wafer section 104 from carrier tape 102 and transfer it to a suitable substrate, as described in further detail below in conjunction with FIGS. 4A-5. To aid in removing wafer section 104 from carrier tape 102, one or more ejector pins 116 may be utilized. Ejector pins 116 are operable to provide a force to the bottom of wafer sections 104 through carrier tape 102. Once removed from carrier tape 102, vacuum device 114 transfers wafer section 104 to a substrate 400, such as the one as illustrated in FIGS. 4A-4B.

Referring first to FIG. 4A, a wafer section 104a is shown to be placed onto solder 402 disposed outwardly from substrate 400. Solder 402 may be any suitable amount of any suitable solder used to couple wafer section 104a to substrate 400. Substrate 400 may be any suitable substrate, such as a leadframe or other suitable substrate.

In the embodiment in FIG. 4A, wafer section 104a includes a first die part 406 and a second die part 407. Die part 406 and die part 407 of wafer section 104a in this embodiment have dependent functionality such that various contact pads 405 existing on die parts 406 and 407 are interconnected by one or more wire bonds 404. Some of these contact pads 405 may also function to electrically couple die part 406 and/or die part 407 to substrate 400 and/or metal features to the outside of the package.

Referring now to FIG. 4B, a wafer section 104b is shown to be coupled to substrate 400 with solder 402. However, in this embodiment, wafer section 104b includes a first die 409 and a second die 411. Die 409 and die 411 have independent functionality and may or may not be electrically coupled to one another with wire bonds 404. In addition, die 409 and/or die 411 may be coupled to substrate 400. Thus, FIGS. 4A and 4B illustrate one technical advantage of the invention in that, due to channels 144 of wafer sections 104, the solder cannot rise in the space between separate die parts, such as die part 406 and die part 407, or separate die, such as first die 409 and second die 411.

FIG. 5 is a cross-sectional view of an integrated circuit package 500 according to one embodiment of the invention. In the illustrated embodiment, integrated circuit package 500 includes a wafer section 104 coupled to substrate 400 with solder 402 and encapsulated with a molding 501, which may be any suitable encapsulation material, such as a suitable plastic encapsulant. FIG. 5 illustrates another technical advantage of the invention in that large die sizes may be utilized because expected fracture areas may be accounted for in the solder die attach process. More specifically, as illustrated in FIG. 5, a crack 502 has developed at the bottom of a trough 503 formed during the partial partitioning process as described above in conjunction with FIGS. 2A-2B. Crack 502 may propagate down through the silicon and into solder 402. This crack develops during use because of the mechanical stress that is caused during temperature changes and the mismatch of the coefficient of thermal expansion (“CTE”) between wafer section 104 and solder 402. Thus, wafer section 104 is designed to account for this expected failure during use and, hence, larger die sizes may be utilized for the solder die attach process.

Although embodiments of the invention and their advantages are described in detail, a person skilled in the art could make various alterations, additions, and omissions without departing from the spirit and scope of the present invention, as defined by the appended claims.

What is claimed is:

1. A method of solder die attach, comprising:
providing a wafer disposed outwardly from a carrier tape;
partitioning the wafer into a plurality of wafer sections;
partially partitioning at least some of the wafer sections;
picking up a first wafer section of the partially partitioned wafer sections; and
placing the first wafer section onto solder disposed outwardly from a substrate.

2. The method of claim 1, wherein partitioning the wafer into a plurality of wafer sections comprises:
partially partitioning the wafer to form a plurality of first troughs in the wafer; and
partitioning the wafer to form a plurality of second troughs at the bottom of respective first troughs, the second troughs thinner than the first troughs.

3. The method of claim 1, wherein partitioning the wafer into a plurality of wafer sections comprises partitioning the wafer into a rectangular or square array of wafer sections.

4. The method of claim 1, wherein picking up a first wafer section further comprises applying a force to the bottom of the a first wafer section with an ejector pin.

5. The method of claim 1, wherein the first wafer section comprises first and second die, the method further comprising electrically coupling the first and second die.

6. The method of claim 1, wherein at least some of the wafer sections comprise first and second die having independent functionality.

7. The method of claim 1, wherein at least some of the wafer sections comprise first and second die having dependent functionality.

8. The method of claim 1, wherein at least some of the wafer sections comprise multiple die having independent functionality.

9. A system of solder die attach, comprising:
a carrier tape;
a wafer disposed outwardly from the carrier tape;
a cutting device partitioning the wafer into a plurality of wafer sections by cutting through a thickness of the wafer and at least partially through a thickness of the carrier tape;
the cutting device partially partitioning at least some of the wafer sections by cutting partially through the thickness of the wafer;
a vacuum device picking up a first wafer section of the partially partitioned wafer sections; and
the vacuum device placing the first wafer section onto solder disposed outwardly from a substrate.

10. The system of claim 9, wherein partitioning the wafer comprises the cutting device partially partitioning the wafer to form a plurality of first troughs in the wafer, and partitioning the wafer to form a plurality of second troughs at the bottom of respective first troughs, the second troughs thinner than the first troughs.

11. The system of claim 9, wherein the cutting device partitions the wafer into a rectangular or square array of wafer sections.

12. The system of claim 9, further comprising one or more ejector pins operable to apply a force to the bottom of the a first wafer section as the vacuum device is picking up the first wafer section.

13. The system of claim 9, wherein the first wafer section comprises first and second die, and wherein the vacuum device comprises two multiple vacuum nozzles associated therewith.

14. The system of claim 9, wherein at least some of the wafer sections comprise first and second die having independent functionality.

15. The system of claim 9, wherein at least some of the wafer sections comprise first and second die having dependent functionality.

16. The system of claim 9, wherein at least some of the wafer sections comprise multiple die having independent functionality.

17. A method of solder die attach, comprising:
providing a wafer;
partitioning the wafer into a plurality of wafer sections by cutting through a thickness of the wafer; and
partially partitioning the wafer sections by cutting partially through the thickness of the wafer.

18. The method of claim 17, further comprising:
picking up a first wafer section of the partially partitioned wafer sections; and
placing the first wafer section onto solder disposed outwardly from a substrate.

19. The method of claim 17, wherein at least some of the wafer sections comprise first and second die having independent functionality.

20. The method of claim 17, wherein at least some of the wafer sections comprise first and second die having dependent functionality.
